(19) United States
(12) Patent Application Publication
(10) Pub. No.: US 2021/0376193 A1
(43) Pub. Date: Dec. 2, 2021

(54) LIGHT-EMITTING DEVICE, METHOD OF PREPARING SAME, INK COMPOSITION INCLUDING SAME, AND APPARATUS INCLUDING SAME

(71) Applicant: Samsung Display Co., Ltd., Yongin-si (KR)

(72) Inventors: Yunhyuk KO, Yongin-si (KR); Changhee LEE, Yongin-si (KR); Yunku JUNG, Yongin-si (KR); Dukki KIM, Yongin-si (KR); Jongwon PARK, Yongin-si (KR); Jaekook HA, Yongin-si (KR)

(21) Appl. No.: 17/331,510

(22) Filed: May 26, 2021

(30) Foreign Application Priority Data
May 27, 2020 (KR) 10-2020-0063889

(51) Int. Cl. H01L 33/32; H01L 33/04; H01L 33/00

(52) U.S. Cl. CPC H01L 33/325; H01L 33/0075; H01L 33/04

(57) ABSTRACT

Provided are a light-emitting device, a method of preparing the light-emitting device, an ink composition including the light-emitting device, and an apparatus including the light-emitting device. The light-emitting device may include: a semiconductor region including a first semiconductor layer, a second semiconductor layer, and an active layer between the first semiconductor layer and the second semiconductor layer; a first protective layer on at least one portion of a surface of the semiconductor region and including a Group III-V compound; and a second protective layer on the first protective layer and including a metal oxide.

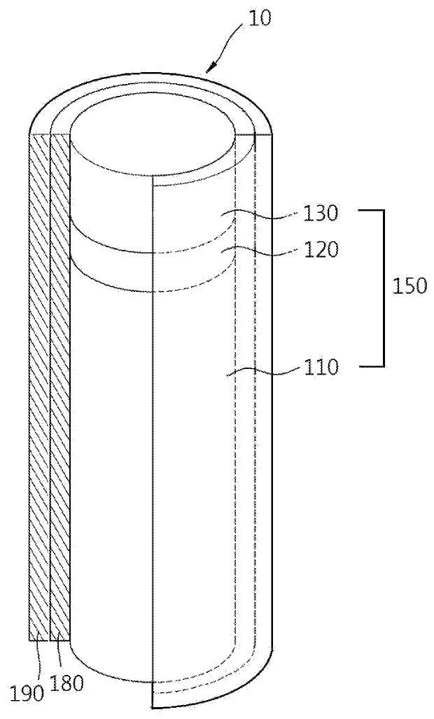

### CROSS-REFERENCE TO RELATED APPLICATION

This application claims priority to and the benefit of Korean Patent Application No. 10-2020-0063889, filed on May 27, 2020, in the Korean Intellectual Property Office, the entire content of which is hereby incorporated by reference.

### BACKGROUND

### 1. Field

One or more embodiments of the present disclosure relate to a light-emitting device, a method of preparing the light-emitting device, an ink composition including the light-emitting device, and an apparatus including the light-emitting device.

### 2. Description of Related Art

Light-emitting devices (LEDs) have high light conversion efficiency, consume relatively very little energy, and are semi-permanent and eco-friendly. In order to utilize LEDs as lighting or a display device, the LEDs may be coupled between a pair of electrodes capable of applying power to the LEDs. A method of coupling LEDs to electrodes may be classified into a method of directly growing LEDs on a pair of electrodes and a method of arranging LEDs after separately growing the LEDs. In the latter method, a solution process may be used as a method of inputting or arranging LEDs on electrodes. For example, LEDs may be input or arranged on electrodes by using a slit coating method and/or an inkjet printing method.

When a Group III-V semiconductor nanoparticle is used as an LED material, upon forming an insulating film on a surface of the semiconductor nanoparticle, a lattice defect may be generated at an interface between the semiconductor compound and the insulating film, thereby deteriorating the efficiency of the LED. In addition, due to coating the insulating film by using an atomic layer deposition (ALD) process, a process of providing a precursor material of the insulating film and removing the residue may be performed repeatedly, and thus, the growth rate of the thin film may be slow, and the manufacturing cost may be increased.

### SUMMARY

One or more embodiments of the present disclosure include a light-emitting device having decreased lattice defects and improved efficiency, a method of preparing the light-emitting device, an ink composition including the light-emitting device, and an apparatus including the light-emitting device.

Additional aspects of embodiments will be set forth in part in the description which follows and, in part, will be apparent from the description, or may be learned by practice of the presented embodiments of the disclosure.

According to one or more embodiments, a light-emitting device may include:

a semiconductor region including a first semiconductor layer, a second semiconductor layer, and an active layer between the first semiconductor layer and the second semiconductor layer;

a first protective layer on at least one portion of a surface of the semiconductor region and including a Group III-V compound; and

a second protective layer on the first protective layer and including a metal oxide.

According to one or more embodiments, a method of preparing a light-emitting device may include, wherein the light-emitting device may include: a semiconductor region including a first semiconductor layer, a second semiconductor layer, and an active layer between the first semiconductor layer and the second semiconductor layer; a first protective layer on at least one portion of a surface of the semiconductor region; and a second protective layer on the first protective layer,

forming the first protective layer including a Group III-V compound on at least one portion of a surface of the semiconductor region; and

forming the second protective layer including a metal oxide on the first protective layer.

According to one or more embodiments, an ink composition may include the light-emitting device.

According to one or more embodiments, an apparatus may include the light-emitting device.

### BRIEF DESCRIPTION OF THE DRAWING

The above and other aspects and features of certain embodiments of the disclosure will be more apparent from the following description taken in conjunction with the accompanying drawing, which is a schematic cross-sectional view of a light-emitting device according to an embodiment.

### DETAILED DESCRIPTION

Reference will now be made in more detail to embodiments, examples of which are illustrated in the accompanying drawing, wherein like reference numerals refer to like elements throughout. In this regard, the present embodiments may have different forms and should not be construed as being limited to the descriptions set forth herein. Accordingly, the embodiments are merely described below, by referring to the accompanying drawing, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the subject matter of the present disclosure allows for various changes and numerous embodiments, particular embodiments will be illustrated in the drawing and described in more detail in the written description. Effects, features, and a method of achieving embodiments of the present disclosure will be readily apparent to those of ordinary skill in the art by referring to example embodiments of the present disclosure with reference to the attached drawing. The subject matter of the present disclosure may, however, be embodied in many different forms and should not be construed as being limited to the embodiments set forth herein.

It will be understood that, although the terms first, second, etc. may be used herein to describe various elements, these elements should not be limited by these terms. These terms are only used to distinguish one element from another.

In the embodiments described in the present specification, an expression used in the singular encompasses the expression of the plural, unless it has a clearly different meaning in the context.

In the present specification, it is to be understood that the terms such as “including,” “having,” and “comprising” are intended to indicate the presence of the features or components disclosed in the specification, and are not intended to preclude the possibility that one or more other features or components may be present or may be added. For example, unless otherwise limited, terms such as “including” or “having” may refer to either consisting of features or components described in the specification only or further including other components.

### Light-Emitting Device

Hereinafter, a light-emitting device according to an embodiment and a method of preparing the light-emitting device will be described with reference to the accompanying drawing.

The light-emitting device 10 may include a semiconductor region 150, and the semiconductor region 150 may include a first semiconductor layer 110, a second semiconductor layer 130, and an active layer 120 between the first semiconductor layer 110 and the second semiconductor layer 130.

In addition, the light-emitting device 10 may include: a first protective layer 180 on at least one portion of the semiconductor region 150 and including a Group III-V compound; and a second protective layer 190 on the first protective layer 180 and including a metal oxide.

The first semiconductor layer 110, the active layer 120, and the second semiconductor layer 130 may be sequentially stacked in a longitudinal direction of the light-emitting device.

In some embodiments, the first semiconductor layer may include an n-type semiconductor layer, and the second semiconductor layer may include a p-type semiconductor layer. The semiconductor layer may include a semiconductor compound having a chemical formula (or an empirical formula) of InₓAl_{y}Ga_{1-x-y}N (wherein 0≤x≤1, 0≤y≤1, and 0≤x+y≤1), for example, examples of the semiconductor compound may include GaN, AlN, AlGaN, InGaN, InN, InAlGaN, and AlInN.

In some embodiments, the first semiconductor layer may be doped with an n-type dopant such as Si, Ge, and/or Sn.

In some embodiments, the first semiconductor layer may include GaN doped with an n-type dopant.

In some embodiments, the second semiconductor layer may include a p-type dopant such as Mg, Zn, Ca, Sr, and/or Ba.

In some embodiments, the second semiconductor layer may include GaN doped with a p-type dopant.

In some embodiments, the first semiconductor layer may include a p-type semiconductor, and the second semiconductor layer may include an n-type semiconductor layer.

The active layer 120 may be between the first semiconductor layer 110 and the second semiconductor layer 130.

In some embodiments, the active layer 120 may include a single quantum well structure or a multiple quantum well structure.

In some embodiments, when the active layer 120 includes a material having a multiple quantum well structure, the active layer 120 may have a structure in which quantum layers and well layers are alternately stacked. In some embodiments, the active layer 120 may have a structure in which a semiconductor material having a high band gap energy and a semiconductor material having a low band gap energy are alternately stacked. In some embodiments, the active layer 120 may include different semiconductor materials depending on the wavelength of emitted light.

The active layer 120 may be a region in which electrons and holes are recombined according to the electrical signal applied through the first semiconductor layer 110 and the second semiconductor layer 130. As electrons and holes are recombined, a transition from a higher energy level to a lower energy level may occur, thus emitting light having a wavelength corresponding to the lower energy level (or corresponding to the energy difference between the higher energy level and the lower energy level). The active layer may be used without limitation as long as the active layer is an active layer that may be included in an LED device used in the art for lighting, display, and/or the like.

The light-emitting device 10 may include: a first protective layer 180 on at least one portion of the semiconductor region 150 and including a Group III-V compound (e.g., a compound including a Group III element and a Group V element); and a second protective layer 190 on the first protective layer 180 and including a metal oxide.

In some embodiments, the first protective layer 180 may surround (e.g., partially or completely surround) the semiconductor region 150, and the second protective layer 190 may surround (e.g., partially or completely surround) the first protective layer 180.

In some embodiments, the first protective layer 180 and/or the second protective layer 190 may surround the whole external surface of the semiconductor region 150 or a portion of the external surface of semiconductor region 150.

The first protective layer 180 may include a Group III-V compound (e.g., a compound including a Group III element and a Group V element).

In some embodiments, a Group III element included in the Group III-V compound may be boron (B), aluminum (Al), gallium (Ga), indium (In), or any combination thereof.

In some embodiments, a Group V element included in the Group III-V compound may be nitrogen (N), phosphorus (P), arsenic (As), antimony (Sb), or any combination thereof.

In some embodiments, the Group III-V compound may be selected from a binary compound selected from the group consisting of GaN, GaP, GaAs, GaSb, AlN, AlP, AlAs, AlSb, InN, InP, InAs, InSb and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The first protective layer 180 may be between the semiconductor region 150 and the second protective layer 190 to thereby reduce a lattice defect (e.g., reduce a likelihood or degree of a lattice defect). Accordingly, the light-emitting device may have improved luminescence efficiency.

In some embodiments, a degree of lattice mismatch between the semiconductor region and the first protective layer may be 3 percent (%) or lower, or for example, 1% or lower.

In some embodiments, a degree of lattice mismatch between the first protective layer and the second protective layer may be 5% or lower, or for example, 3% or lower.

The second protective layer 190 may include a metal oxide.

In some embodiments, the metal oxide may include Al₂O₃, ZrO₂, SiO₂, TiO₂, ZnO, or any combination thereof.

In some embodiments, the second protective layer may be an insulating layer.

In some embodiments, the thickness of the second protective layer may be in a range of about 10 nanometers (nm) to about 700 nm, for example, about 20 nm to about 500 nm, or for example, about 50 nm to about 100 nm.

The second protective layer may prevent or reduce a decrease in luminescence efficiency by protecting an external surface of the light-emitting device including an external surface of the semiconductor region 150.

In addition, when performing a nanorod-pattern etching process on the first protective layer 180 and the second protective layer 190, a lattice defect at a surface of a light-emitting device may decrease (e.g., a likelihood or degree of the lattice defect may decrease).

In some embodiments, the light-emitting device 10 may be in various suitable shapes such as, for example a cylindrical shape, a cuboid shape, a wire, or a tube, but the present disclosure is not limited thereto. In some embodiments, the light-emitting device may be in a cylindrical shape.

The light-emitting device 10 may be a nano light-emitting device (nano LED), which is a light-emitting device having a size of nano-scale, or a micro light-emitting device (micro LED), which is a light-emitting device having a size of micro-scale.

For example, a diameter of the light-emitting device 10 may be in a range of about 0.1 micrometers (μm) to about 1 μm, and a length of the light-emitting device may be in a range of about 1 μm to about 10 μm.

The light-emitting device 10 may emit red light, green light, and/or blue light.

In some embodiments, the first protective layer 180 may be formed by a wet chemical reaction. In addition, in some embodiments, the second protective layer 190 may be formed by a wet chemical reaction. The method of forming of the first protective layer and the second protective layer may be understood by referring to the description of the method of forming a light-emitting device provided herein.

When the wet chemical reaction is used to form the first protective layer 180 and/or the second protective layer 190, a lattice defect on the semiconductor region may be reduced (e.g., a likelihood or degree of a lattice defect may be reduced), while forming a protective layer, thereby improving efficiency of a light-emitting device. In addition, controlling a growth rate of a thin film may be facilitated to thereby control the thickness of the protective layers and improve process characteristics.

In some embodiments, the wet chemical reaction may be a sol-gel reaction.

In some embodiments, the light-emitting device may further include a fluorescent material layer, an active layer, a semiconductor layer, and/or an electrode layer on the first semiconductor layer and below the second semiconductor layer.

Light generated from the active layer 120 may be emitted through an external surface and/or lateral surfaces of the light-emitting device. For example, the directionality of light emitted from active layer 120 is not limited to one direction.

According to one or more embodiments, the light-emitting device may further include a first electrode layer under the first semiconductor layer and/or a second electrode layer on the second semiconductor layer.

The first electrode layer and the second electrode layer may each be an ohmic contact electrode. However, the first electrode layer and the second electrode layer are not limited thereto, and the first electrode layer and the second electrode layer may each be a Schottky contact electrode (e.g., an electrode formed by a junction of a semiconductor and a metal). The first electrode layer and the second electrode layer may include, for example, at least one metal such as aluminum, titanium, indium, gold, and/or silver. Materials included in the first electrode layer and the second electrode layer may be identical to or different from each other.

### Method of Preparing Light-Emitting Device

According to one or more embodiments, when a light-emitting device includes: a semiconductor region including a first semiconductor layer, a second semiconductor layer, and an active layer between the first semiconductor layer and the second semiconductor layer; a first protective layer on at least one portion of a surface of the semiconductor region; and a second protective layer on the first protective layer, a method of preparing the light-emitting device may include,

forming the first protective layer including a Group III-V compound on at least one portion of a surface of the semiconductor region; and

forming the second protective layer including a metal oxide on the first protective layer.

The forming of the first protective layer may be performed by a wet chemical reaction.

For example, the forming of the first protective layer may be performed by a sol-gel reaction.

In some embodiments, the forming of the first protective layer may include reacting a precursor including a Group III element with a precursor including a Group V element in a solution including a surfactant.

In some embodiments, the forming of the first protective layer may include:

Process (a): impregnating a structure, in which the first semiconductor layer, the active layer, and the second semiconductor layer are stacked, with a solution including a surfactant,

Process (b): adding a precursor including a Group III element to the solution,

Process (c): adding a precursor including a Group V element to the solution and heating the solution to a temperature in a range of about 100° C. to about 400° C. to allow a reaction to occur, and

Process (d): cooling the solution to room temperature.

However, Processes (a), (b), (c), and (d) are merely examples of forming the first protective layer, and a method of forming of the first protective layer is not limited thereto.

In some embodiments, the precursor including a Group III element may be a halide of a Group III element, an acetate of a Group III element, an acetylacetonate of a Group III element, or any combination thereof.

In some embodiments, a precursor including the Group V element may include bis(trimethylsilyl)amine, hexamethyldisilazane (HDMS), tris(trimethylsilyl)amine, N,N-bis(trimethylsilyl)methylamine, or any combination thereof.

In some embodiments, the surfactant may include oleylamine, oleic acid, hexadecylamine, dodecylamine, or any combination thereof.

In some embodiments, the forming of the first protective layer may be performed at a temperature in a range from about 100° C. to about 400° C., or for example, about 200° C. to about 300° C.

When the wet chemical reaction is used to form the first protective layer including a Group III-V compound, a lattice defect on the semiconductor region may be reduced (e.g., a likelihood or degree of a lattice defect may be reduced), while forming a protective layer, thereby improving efficiency of a light-emitting device. In addition, controlling growth rate of a thin film of the protective layer may be facilitated to thereby control the thickness of the protective layers and improve process characteristics.

The forming of the second protective layer may be performed by a wet chemical reaction.

For example, the forming of the second protective layer may be performed by a sol-gel reaction.

In some embodiments, the forming of the second protective layer and the forming of the first protective layer may be performed as a one-step process.

In some embodiments, the forming of the second protective may include, following or subsequent to Process (d),

Process (e): in the solution, adding a metal oxide precursor to a surface of the structure on which the first protective layer is formed, and

Process (f): maintaining the temperature of the solution in a range from room temperature to a temperature of 200° C. to allow a reaction to occur and forming a second protective layer including a metal oxide.

However, Processes (e) and (f) are merely examples of forming the second protective layer, and a method of forming of the second protective layer is not limited thereto.

In some embodiments, the forming of the second protective layer may be performed at a temperature in a range from room temperature to about 300° C., or for example, room temperature to about 200° C.

When the wet chemical reaction is used to form the second protective layer including a metal oxide, a lattice defect on the semiconductor region may be reduced (e.g., a likelihood or degree of a lattice defect may be reduced), while forming a protective layer, thereby improving efficiency of a light-emitting device. In addition, controlling growth rate of a thin film may be facilitated to thereby control the thickness of the protective layers and improve process characteristics.

### Ink Composition

According to one or more embodiments, an ink composition may include the light-emitting device.

In some embodiments, a content of the light-emitting device in the ink composition may be in a range of about 0.005 parts to about 5 parts by weight, or for example, about 0.01 parts to about 1 part by weight, based on 100 parts by weight of the ink composition. When a content of the light-emitting device is within any of the foregoing ranges, an apparatus having suitable or sufficient luminescence efficiency may be prepared through a solution process by using the ink composition. When a content of the light-emitting device in the ink composition is less than 0.05 parts by weight, and a light-emitting apparatus is manufactured using the ink composition, the number of light-emitting devices coupled to electrodes may be small, and thus, it may be difficult to obtain suitable or sufficient luminescence efficiency, and a problem of dropping solution several times may occur.

The ink composition may further include a solvent, a thickener, a dispersant, and/or the like, as necessary or desired, to thereby have a viscosity and a dispersing stability suitable for the process.

The dispersant may be used to improve a deagglomeration effect of the light-emitting device in the ink composition and to serve as a protective layer for the light-emitting device in a solution process.

The dispersant may be a resin type dispersant, such as a phosphoric acid ester-based dispersant, a urethane-based dispersant, an acrylic dispersant, and/or the like. For example, examples of commercially available dispersants may include DISPER BYK-103, DISPER BYK-110, DISPER BYK-111, DISPER BYK-2000, DISPER BYK-2001, DISPER BYK-2011, DISPER BYK-2070, DISPER BYK-2150, DISPER BYK-160, DISPER BYK-161, DISPER BYK-162, DISPER BYK-163, DISPER BYK-164, and DISPER BYK-166, each available from Byk-Chemie GmbH.

A content of the dispersant may be in a range of about 10 parts to about 50 parts by weight, or for example, about 15 parts to about 30 parts by weight, based on 100 parts by weight of the light-emitting device. When a content of the dispersant is within any of the foregoing ranges, aggregation of the light-emitting device in the ink composition may be substantially prevented or reduced, and the dispersant may serve as a protective layer for the light-emitting device in a solution process.

In addition, the ink composition may further include an adhesion promoter for increasing adhesion to a substrate, a leveling agent for improving coating properties, an antioxidant, an ultraviolet absorber, and/or any combination thereof, as necessary or desired.

The adhesion promoter may be added to enhance adhesion to a substrate. Examples of the adhesion promoter may include a silane coupling agent having a reactive substituent selected from a carboxyl group, a methacryloyl group, an isocyanate group, an epoxy group, and a combination thereof, but embodiments of the present disclosure are not limited thereto. For example, the silane coupling agent may be trimethoxysilyl benzoate, γ-methacryloxypropyltrimethoxysilane, vinyltriacetoxysilane, vinyltrimethoxysilane, γ-isocyanatopropyl triethoxysilane, γ-glycidoxypropyltrimethoxysilane, β-(3,4-epoxycyclohexyl)ethyltrimethoxysilane, or any combination thereof.

Examples of the leveling agent include a silicon-based compound, a fluorine-based compound, a siloxane-based compound, a nonionic surfactant, an ionic surfactant, and a titanate coupling agent, but embodiments of the present disclosure are not limited thereto. For example, the leveling agent may be a silicon-based compound and/or a fluorine-based compound.

Examples of the silicon-based compound include dimethyl silicon, methyl silicon, phenyl silicon, methyl phenyl silicon, alkyl-modified silicon, alkoxy-modified silicon, and polyether-modified silicon, but embodiments of the present disclosure are not limited thereto. For example, the silicon-based compound may be dimethyl silicon and/or methyl phenyl silicon.

Examples of the fluorine-based compound include polytetrafluorethylene, polyvinylidene fluoride, fluoroalkyl methacrylate, perfluoropolyether, and perfluoroalkylethylene oxide, but embodiments of the present disclosure are not limited thereto. For example, the fluorine-based compound may be polytetrafluorethylene.

Examples of the siloxane-based compound include dimethyl siloxane compound (e.g., Product No: KF96L-1, KF96L-5, KF96L-10, or KF96L-100 each available from Shinetsu Silicone), but embodiments of the present disclosure are not limited thereto.

The leveling agent may be used alone or in combination with two or more types thereof.

A content of the leveling agent may vary depending on the desired performance, and the content may be in a range of about 0.001 wt % to about 5 wt %, or for example, about 0.001 wt % to about 1 wt %, based on the total weight of the ink composition. When the content of the leveling agent is within any of the foregoing ranges, flowability and uniformity of a film in the ink composition may be improved.

In some embodiments, the ink composition may have excellent inkjet ejection stability, and thus, the ink composition may be, for example, an ink composition for inkjet printing.

### Apparatus

According to one or more embodiments, an apparatus may include the light-emitting device.

In some embodiments, the apparatus may include a substrate; a first electrode and a second electrode that may be spaced apart from each other on the substrate; and a light-emitting device between the first electrode and the second electrode.

In some embodiments, the substrate may include a display region and a non-display region around the display region, and the first electrode and the second electrode may be spaced apart from each other on the display region.

For example, the apparatus may be a light-emitting apparatus, an authentication apparatus, and/or an electronic apparatus, but embodiments are not limited thereto.

The light-emitting apparatus may be used in various suitable displays, light sources, and/or the like.

The authentication apparatus may be, for example, a biometric authentication apparatus that identifies an individual according biometric information (e.g., a fingertip, a pupil, and/or the like).

The authentication apparatus may further include a biometric information collecting unit.

The electronic apparatus may be applicable to a personal computer (e.g., a mobile personal computer), a cellphone, a digital camera, an electronic note (e.g., an electronic notebook), an electronic dictionary, an electronic game console, a medical device (e.g., an electronic thermometer, a blood pressure meter, a glucometer, a pulse measuring device, a pulse wave measuring device, an electrocardiograph recorder, an ultrasonic diagnosis device, and/or an endoscope display device), a fish finder, various suitable measurement devices, gauges (e.g., gauges of an automobile, an airplane, and/or a ship), and/or a projector, but embodiments are not limited thereto.

In an embodiment, the apparatus may be a light-emitting apparatus.

In an embodiment, the apparatus may include a liquid crystal display (LCD), an organic light-emitting display apparatus and/or an inorganic light-emitting display apparatus.

The apparatus may further include a thin film transistor.

Hereinafter, a light-emitting device according to one or more embodiments will be described in more detail with reference to Examples, but the present disclosure is not limited thereto.

### EXAMPLES

### Comparative Example 1

A GaN nanorod was formed by sequentially depositing n-doped GaN, an emission layer, and p-doped GaN and KOH etching. AlGaN was formed as a protective layer on a surface of the GaN nanorod to manufacture a light-emitting device.

### Comparative Example 2

A light-emitting device was manufactured in substantially the same manner as in formation of the GaN nanorod in Comparative Example 1, except that GaN was formed as a protective layer.

### Comparative Example 3

A light-emitting device was manufactured in substantially the same manner as in formation of the GaN nanorod in Comparative Example 1, except that an Al₂O₃ protective layer was formed on a surface thereof by atomic layer deposition (ALD).

### Comparative Example 4

A light-emitting device was manufactured in substantially the same manner as in formation of the GaN nanorod in Comparative Example 1, except that an Al₂O₃ protective layer was formed on a surface thereof by a wet chemical reaction using 1,2-ethanedithiol.

### Example 1

A light-emitting device was manufactured in substantially the same manner as in formation of the GaN nanorod in Comparative Example 1, except that a Group 111-V compound protective layer was formed by a wet chemical reaction on a surface thereof, and an Al₂O₃ protective layer was formed by a wet chemical reaction on a surface of the Group 111-V compound protective layer.

### Evaluation Example 1: Lattice Defect Evaluation

The lattice defects of the light-emitting devices manufactured in Example 1 and Comparative Examples 1 to 4 were evaluated using variable-energy positron annihilation. The results thereof are shown in Table 1.

TABLE 1

| Light-emitting device | Degree of lattice mismatch (%) |
|---|---|
| Example 1 | 0.36 |
| Comparative Example 1 | 0.56 |
| Comparative Example 2 | — |
| Comparative Example 3 | 13.8 |
| Comparative Example 4 | 10.8 |

Referring to the results of Table 1, the light-emitting device according to one or more embodiments was found to have a low degree of lattice mismatch, as compared with the light-emitting devices of Comparative Examples 1, 3, and 4. In the light-emitting device of Comparative Example 2, the semiconductor region and the protective layer were formed using the same material, and thus, unlike the light-emitting device of Example 1, the protective layer may not complement the lattice defect on a surface of the light-emitting device generated during nanorod pattern etching process. Accordingly, when the light-emitting device according to one or more embodiments is applied to a light-emitting apparatus, high luminescence efficiency may be obtained.

As is apparent from the foregoing description, as a first protective layer and a second protective layer are formed on a surface of a semiconductor region in the light-emitting device, a lattice defect may be reduced, and efficiency may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the accompanying drawing, it will be understood by those of ordinary skill in the art that various changes in form and details may be made therein without departing from the spirit and scope of the present disclosure as defined by the following claims, and equivalents thereof.

What is claimed is:

1. A light-emitting device comprising:
a semiconductor region comprising a first semiconductor layer, a second semiconductor layer, and an active layer between the first semiconductor layer and the second semiconductor layer;
a first protective layer on at least one portion of a surface of the semiconductor region and comprising a Group III-V compound; and
a second protective layer on the first protective layer and comprising a metal oxide.

2. The light-emitting device of claim 1, wherein the semiconductor region comprises a semiconductor compound having a chemical formula of InₓAl_{y}Ga_{1-x-y}N, wherein 0≤x≤1, 0≤y≤1, and 0≤x+y≤1.

3. The light-emitting device of claim 1, wherein the first semiconductor layer comprises GaN doped with an n-type dopant, and the second semiconductor layer comprises GaN doped with a p-type dopant.

4. The light-emitting device of claim 1, wherein the active layer comprises a single quantum well structure or a multiple quantum well structure.

5. The light-emitting device of claim 1, wherein a Group III element in the Group III-V compound comprised in the first protective layer comprises boron (B), aluminum (Al), gallium (Ga), indium (In), or any combination thereof, and
a Group V element in the Group III-V compound comprised in the first protective layer comprises nitrogen (N), phosphorus (P), arsenic (As), antimony (Sb), or any combination thereof.

6. The light-emitting device of claim 1, wherein the Group III-V compound is selected from GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any combination thereof.

7. The light-emitting device of claim 1, wherein the second protective layer is an insulating layer.

8. The light-emitting device of claim 1, wherein the metal oxide comprises Al₂O₃, ZrO₂, SiO₂, TiO₂, ZnO, or any combination thereof.

9. The light-emitting device of claim 1, wherein a thickness of the second protective layer is in a range of about 50 nanometers (nm) to about 1,000 nm.

10. The light-emitting device of claim 1, wherein the first protective layer reduces a lattice defect between the semiconductor region and the second protective layer.

11. The light-emitting device of claim 1, wherein a degree of lattice mismatch between the semiconductor region and the first protective layer is 1 percent (%) or lower, and a degree of lattice mismatch between the first protective layer and the second protective layer is 3% or lower.

12. The light-emitting device of claim 1, wherein the first protective layer and the second protective layer are each formed by a wet chemical reaction.

13. A method of preparing a light-emitting device, the method comprising:
forming a first protective layer comprising a Group III-V compound on at least one portion of a surface of a semiconductor region; and
forming a second protective layer comprising a metal oxide on a first protective layer,
wherein the semiconductor region comprises a first semiconductor layer, a second semiconductor layer, and an active layer between the first semiconductor layer and the second semiconductor layer.

14. The method of claim 13, wherein the semiconductor region comprises a semiconductor compound having a chemical formula of InₓAl_{y}Ga_{1-x-y}N, wherein 0≤x≤1, 0≤y≤1, and 0≤x+y≤1.

15. The method of claim 13, wherein the forming of the first protective layer is performed by a wet chemical reaction.

16. The method of claim 15, wherein the forming of the first protective layer comprises: reacting a precursor comprising a Group III element with a precursor comprising a Group V element in a solution comprising a surfactant.

17. The method of claim 16, wherein the surfactant comprises oleylamine, oleic acid, hexadecylamine, dodecylamine, or any combination thereof.

18. The method of claim 13, wherein the forming of the second protective layer is performed by a wet chemical reaction, and the forming of the first protective layer and the forming of the second protective layer are performed as a one-step process.

19. An ink composition comprising the light-emitting device of claim 1.

20. An apparatus comprising the light-emitting device of claim 1.
